(19) United States
(12) Patent Application Publication
(10) Pub. No.: US 2015/0095604 A1
(43) Pub. Date: Apr. 2, 2015

(54) CONTROL DEVICE THAT SELECTIVELY REFRESHES MEMORY

(71) Applicant: FUJITSU LIMITED, Kawasaki-shi (JP)

(72) Inventor: Tsunehisa DOI, Kawasaki (JP)

(73) Assignee: FUJITSU LIMITED, Kawasaki-shi (JP)

(21) Appl. No.: 14/561,847

(22) Filed: Dec. 5, 2014

Related U.S. Application Data
(63) Continuation of application No. PCT/JP2012/064723, filed on Jun. 7, 2012.

(51) Int. Cl. G11C 11/406; G06F 12/08

(52) U.S. Cl. CPC G11C 11/40622; G06F 12/0891
USPC 711/166; 711/154

(57) ABSTRACT

A control device includes circuits configured to detect an access request for a memory area in memory that stores information by charging and discharging charge; determining whether any one among write_information written to the memory area that corresponds to the detected access request and read_information read from the memory area coincides with information stored in the memory area when charge is discharged; and performing control to suspend a refresh operation for the memory area when any one among the write_information and the read_information is determined to coincide with the information stored in the memory when the charge is discharged.

### CROSS REFERENCE TO RELATED APPLICATIONS

This application is a continuation application of International Application PCT/JP2012/064723, filed on Jun. 7, 2012 and designating the U.S., the entire contents of which are incorporated herein by reference.

### FIELD

The embodiments discussed herein are related to a control device, a control method, and a computer product.

### BACKGROUND

Dynamic random access memory (DRAM) stores information of “1” or “0” depending on whether stored charge of a memory cell capacitor is present. Stored charge of a capacitor is gradually lost consequent to minute pn junction leaks and therefore, in a system that includes DRAM, a refresh operation of periodically rewriting the same information is performed.

According to a related technology, for example, based on the number of a memory block, which corresponds to a range of preliminarily stored memory addresses, a relevant memory block is selected according to a command from a higher device, and a refresh signal of the memory block is turned ON and OFF. Another technology is for reducing CPU overhead by suspending the refresh operation by a command from a central processing apparatus. According to another technology, in a case where a word line has been activated, thereby activating a refresh instruction signal, if the output of a retaining circuit indicates a value representing that no write history is present, the activation of a sense amplifier drive signal supplied as a driving power source is suspended.

For example, refer to Japanese Laid-Open Patent Publication Nos. H10-177786, H2-048752, and 2003-187577.

Nonetheless, with the conventional technologies, a problem arises in that the refresh operation for retaining information stored to a memory area invites increases in power consumption of the system.

### SUMMARY

According to an aspect of an embodiment, a control device includes circuits configured to detect an access request for a memory area in memory that stores information by charging and discharging charge; determining whether any one among write_information written to the memory area that corresponds to the detected access request and read_information read from the memory area coincides with information stored in the memory area when charge is discharged; and performing control to suspend a refresh operation for the memory area when any one among the write_information and the read_information is determined to coincide with the information stored in the memory when the charge is discharged.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is one example of a control method according to a first embodiment;

FIG. 2 is one example of the control method according to a second embodiment;

FIG. 3 is a diagram depicting an example of system configuration of a system 300;

FIG. 4 is a diagram depicting one example of the stored contents of a clear flag table 400;

FIG. 5 and FIG. 6 are diagrams depicting a concrete example of a packet indicated by an access request;

FIG. 7 is a diagram of an example of a memory cell array of a DRAM 305;

FIG. 8 is a block diagram of a functional configuration example of a control device 101;

FIG. 9 is a diagram of an operation example of a determining unit 802;

FIG. 10 is a diagram of an operation example for a clear process of the system 300;

FIG. 11 is a flowchart (part 1) of an example of a procedure of an updating process by the control device 101;

FIG. 12 is a flowchart (part 2) of an example of the procedure of the updating process by the control device 101;

FIG. 13 is a flowchart (part 3) of the procedure of the updating process by the control device 101; and

FIG. 14 is a flowchart of an example of a procedure of a control process by the control device 101.

### DESCRIPTION OF EMBODIMENTS

Embodiments of a control device, a control method, and a control program will be described in detail with reference to the accompanying drawings.

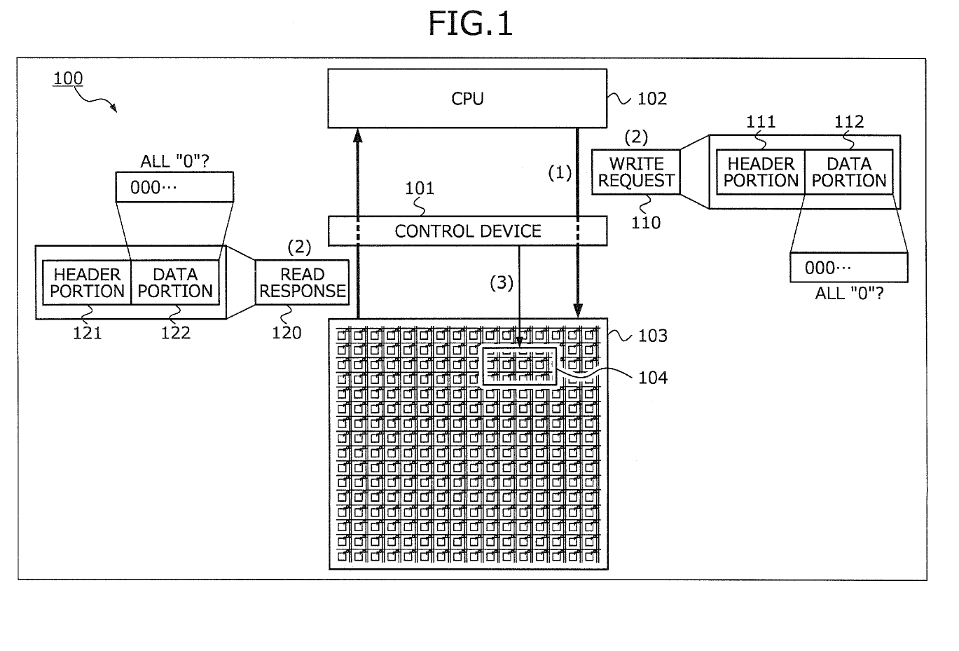

FIG. 1 is one example of the control method according to a first embodiment. In FIG. 1, the system 100 includes a control device 101, a central processing unit (CPU) 102, and memory 103.

The control device 101 controls the reading and writing of information with respect to the memory 103. Further, the control device 101 controls a refresh operation of the memory 103. The CPU 102 governs overall control of the system 100.

The memory 103 is a memory apparatus that stores information by the discharging of charge. For example, the memory 103 stores information of “1” or “0” depending on whether the capacitor of the memory cell has stored charge. The memory cell is a circuit that stores information in units of 1 bit, and includes a transistor and a capacitor.

Here, a refresh operation is a storing/retaining operation of rewriting to a memory cell, the same information stored in the memory cell. Charge stored in the memory cell is gradually lost consequent to minute leaks between an N-type diffusion layer and a P-type substrate. Therefore, the memory 103 performs a refresh operation of periodically rewriting the same information to the memory cell to thereby, prevent a loss of the contents stored in the memory cell. The refresh operation, for example, is performed for each memory cell, in cycles of a few μs or several 10s of μs. In other words, excessive refresh operations occurring in the system 100 invites increased power consumption of the system 100.

Thus, in the first embodiment, the control device 101 suspends the refresh operation for memory areas that among the memory areas in the memory 103, have no need to store information and thereby, suppresses the power consumption for the refresh operation of the memory 103. Hereinafter, an operation example of the control device 101 according to the first embodiment will be described.

(1) The control device 101 detects an access request for a given memory area in the memory 103. An access request is a write request or a read request for the memory area. For example, the control device 101 receives from the CPU 102, an access request for the memory area and thereby, detects the access request for the memory area.

In the example depicted in FIG. 1, an access request for a memory area 104 in the memory 103 is detected. Further, a write request 110 for the memory area 104 is depicted as an example of the access request for the memory area 104.

(2) The control device 101 determines in the case of discharge, if write_information that is to be written to or read_information that is to be read from the memory area corresponding to the detected access request coincides with information stored in the memory area.

Here, write_information, for example, is information that is to be written and is included in a data portion 112 among a header portion 111 and the data portion 112 included in the write request 110 for the memory area 104. Further, read_information, for example, is information that is to be read and is included in the data portion 122, among the header portion 121 and the data portion 122 included in a read response 120 corresponding to a read request (not depicted) for the memory area 104.

Further, the information stored in each memory cell in a case of discharge, is information of “1” or “0”. Whether the information stored in each memory cell in the case of discharge is to be information of “1” or “0” can be arbitrarily set. In the description hereinafter, the information stored in each memory cell in the case of discharge is assumed to be “0”. In this case, the information stored in the memory areas in the case of discharge is an aggregate of the information stored in each memory area in the case of discharge charge, i.e., an aggregate of “0's”.

For example, when the write request 110 for the memory area 104 is detected, the control device 101 determines whether all of the write_information included in the data portion 112 of the write request 110 is “0”. Further, for example, when a read request for the memory area 104 is detected, the control device 101 determines whether the read_information included in the data portion 122 of the read response 120 for the read request are all “0”.

(3) The control device 101 controls the refresh operation for the memory area 104, based on the determination result obtained. For example, the control device 101, upon determining that all of the write_information or the read_information is “0”, suspends the refresh operation for the memory area 104. On the other hand, the control device 101, upon determining that “1” is included in all of the write_information or read_information, does not suspend the refresh operation for the memory area 104.

In this manner, according to the control device 101 of the first embodiment, a write request for a memory area in the memory 103 is detected and if all of the write_information to be written to the memory area is “0”, the refresh operation for the memory area can be suspended. Further, according to the control device 101, when a read request for memory areas is detected and all of the read_information read from the memory areas is “0”, the refresh operation for the memory areas can be suspended. As a result, it can be ensured that the stored content is “0”, i.e., the refresh operation for the memory areas that do not have to retain information is suspended, enabling the power consumption for the refresh operation of the memory 103 to be suppressed.

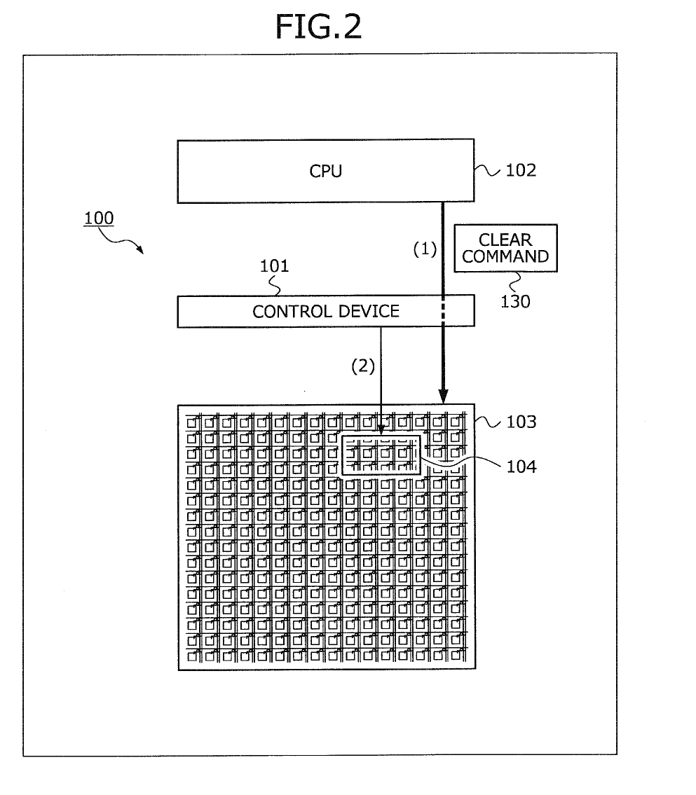

With reference to FIG. 2, an example of the control method according to a second embodiment will be described. In the second embodiment, operation of the control device 101 that uses a clear command for memory areas in the memory 103 will be described. Description of parts identical to those of the first embodiment will be omitted herein.

FIG. 2 is one example of the control method according to the second embodiment. Hereinafter, a control process example of the control device 101 according to the second embodiment will be described.

(1) The control device 101 detects a clear command for a given memory area in the memory 103. The clear command is a command for erasing information stored in the memory area. For example, the control device 101 receives from the CPU 102, a clear command for the memory area and thereby, detects a clear command for the memory area. In the example depicted in FIG. 2, a clear command 130 for a memory area 104 in the memory 103 is detected. In this case, the information stored in the memory area 104 is cleared.

(2) The control device 101, upon detecting a clear command for a memory area, suspends the refresh operation for the memory area. In other words, if there is a clear command for a memory area, the stored contents of the memory area are cleared and the control device 101 suspends the refresh operation for the memory area. In the example depicted in FIG. 2, the control device 101, upon detecting a clear command 130 for the memory area 104, suspends the refresh operation for the memory area 104.

In this manner, according to the control device 101 of the second embodiment, when a clear command for a memory area in the memory 103 is detected, the refresh operation for the memory area can be suspended. As a result, the stored contents can be ensured to be “0”. In other words, the refresh operation for memory areas that have no need to retain information is suspended, enabling the power consumed for the refresh operation of the memory 103 to be suppressed.

An example of system configuration of a system 300 according to the third embodiment will be described. Description of portions identical to those described in the first embodiment and the second embodiment will be omitted.

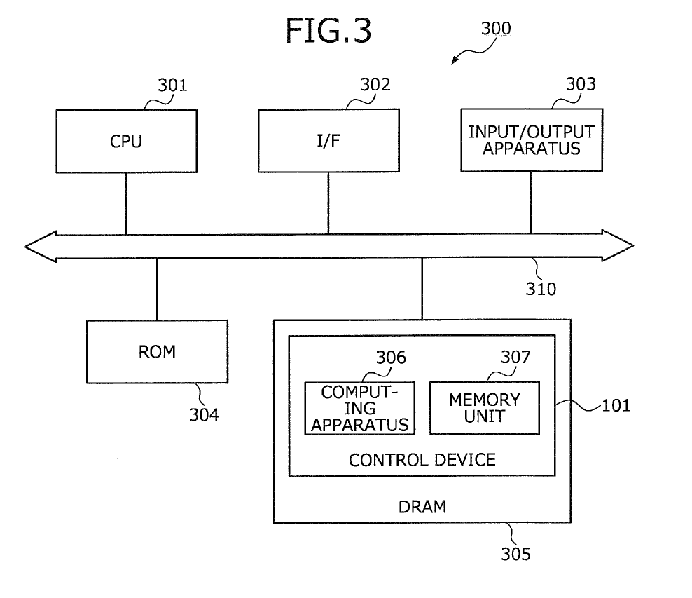

FIG. 3 is a diagram depicting an example of system configuration of the system 300. In FIG. 3, the system 300 has the CPU 301, an interface (I/F) 302, the input/output apparatus 303, read-only memory (ROM) 304, and the DRAM 305, respectively connected by a bus 310.

Here, the CPU 301 governs overall control of the system 300. The I/F 302 is connected, via a communication line, to a network and through the network is connected to another computer. The network, for example, is a local area network (LAN), a wide area network (WAN), and the Internet. The I/F 302 administers an internal interface with the network, and controls the input and output of data from another computer.

The input/output apparatus 303 inputs and outputs information. A display apparatus that displays data such as documents, images, and functional information and a keyboard for inputting text, numerals, and various types of instructions may be used as the input/output apparatus 303, for example. The ROM 304, for example, is a memory apparatus that stores various types of programs.

The DRAM 305, for example, is a memory apparatus that is used as main memory. The DRAM 305 has the control device 101. The control device 101 has a computing apparatus 306 and a memory unit 307, and is a computer that controls the reading and writing of information with respect to the DRAM 305. The computing apparatus 306 administers the control of the control device 101. The memory unit 307 includes ROM and registers. The control device 101 controls the refresh operation for the DRAM 305. The control device 101, for example, is a memory controller.

In addition to the configuration above, the system 300, for example, may have an external memory apparatus, such as a magnetic disk, a magnetic table, and an optical disk.

The stored contents of a clear flag table 400 used by the control device 101 will be described. The clear flag table 400, for example, is implemented by the memory unit 307 of the control device 101 depicted in FIG. 3.

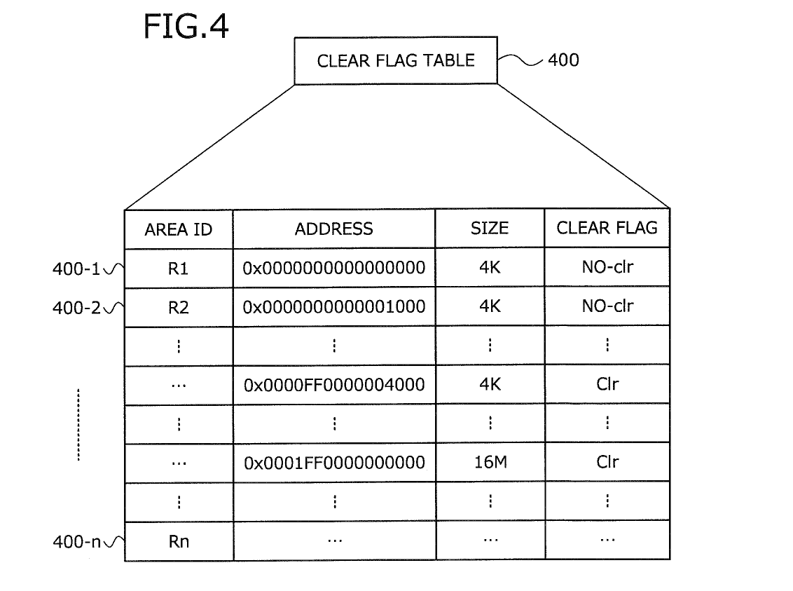

FIG. 4 is a diagram depicting one example of the stored contents of the clear flag table 400. In FIG. 4, the clear flag table 400 has fields for area IDs, addresses, sizes, and clear flags. By setting information into the fields, the clear flag information 400-1 to 400-n is stored as records.

Here, an area ID is an identifier that identifies a memory area of the DRAM 305. A memory area is the unit by which the refresh operation is controlled and, for example, is managed in units of pages of 1[KB], 4[KB], and 16[KB]. An address is the start address of a memory area. The size is the storage capacity of the memory area. The size, for example, is specified by the power of 2. The unit of the size is expressed in, for example, [bytes].

A clear flag is a flag that indicates whether the contents stored in a memory area have been cleared. Clearance completion represents, for example, a state in which the stored contents of the memory area are all “0”. A clear flag of “Clr” indicates that the memory area has been cleared. A clear flag of “No-clr” indicates that the memory area has not been cleared. Further, in an initial state, the clear flag of a memory area is “No-clr”.

Taking the clear flag information 400-1 as an example, for a memory area R1, the address is “0x0000000000000000”; the size is “4K (kilo)” and clear flag indicates “No-clr”.

In the description hereinafter, the plural memory areas in the DRAM 305 are indicated as “the memory areas R1 to Rn” and an arbitrary memory area among the memory areas R1 to Rn may be indicated as “memory area Ri” (i=1, 2, . . . , n).

A concrete example of a packet indicated by an access request for a given memory area in the DRAM 305 will be described. Here, a write request for a memory area will be taken as one example of an access request.

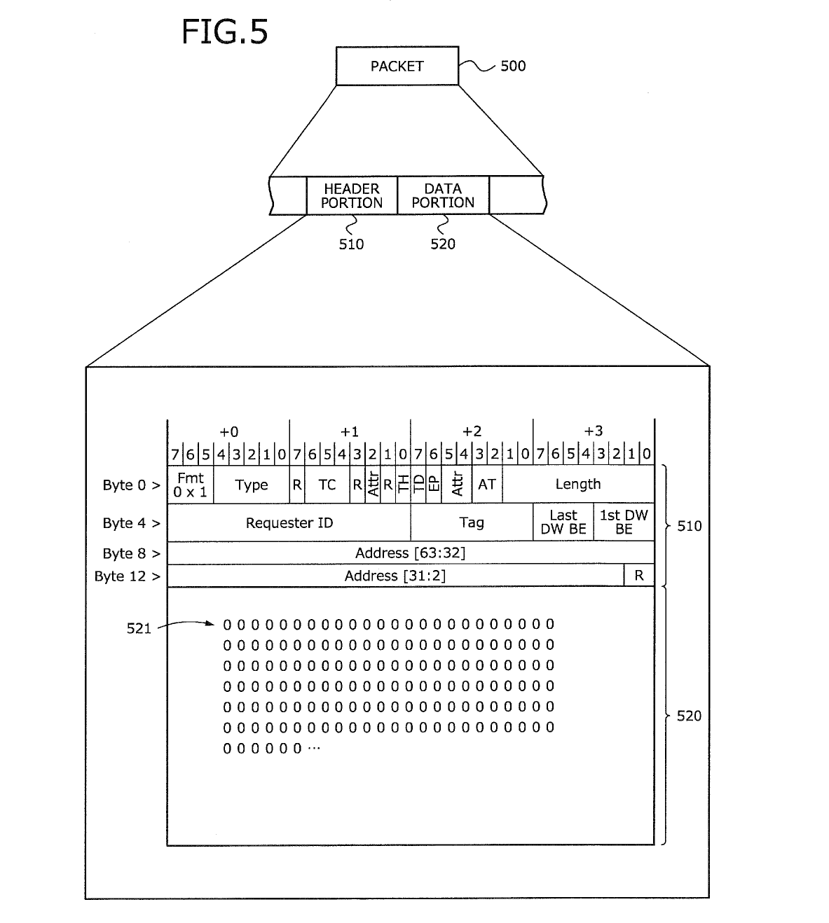

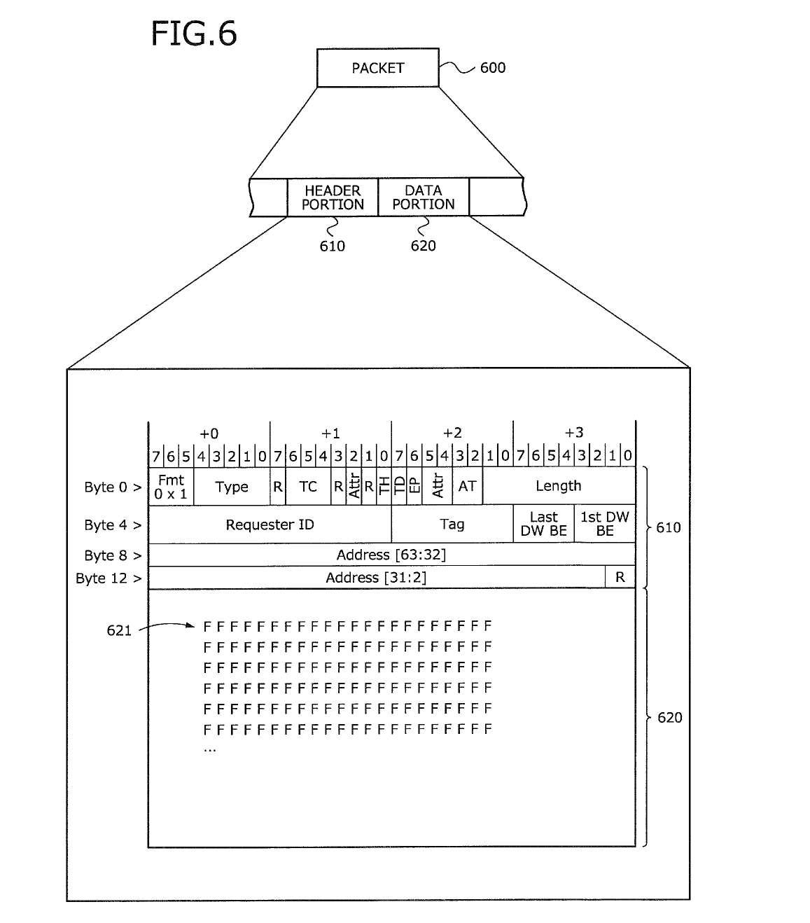

FIG. 5 and FIG. 6 are diagrams depicting a concrete example of a packet indicated by an access request. In FIG. 5, a packet 500 includes a header portion 510 and a data portion 520. In FIG. 6, a packet 600 includes a header portion 610 and a data portion 620.

Here, each header portion 510, 610 includes, for example, the size (in the figure, “Length”) of write_information 521, 621 respectively included in the data portions 520, 620. Further, each header portion 510, 610 includes identification information (in the figure, “Requester ID”) indicating the request source of an access request.

Each header portion 510, 610 includes an access destination address (in the figure, “Address”). Each data portion 520, 620 includes write_information 521, 621. In the example depicted in FIG. 5, the write_information 521 is information of all “0”. Further, in the example of FIG. 6, the write_information 621 is information of all “1”.

Here, a memory cell array of the DRAM 305 will be described. A memory cell array, for example, is a 2-dimensional grid arrangement of the memory cells.

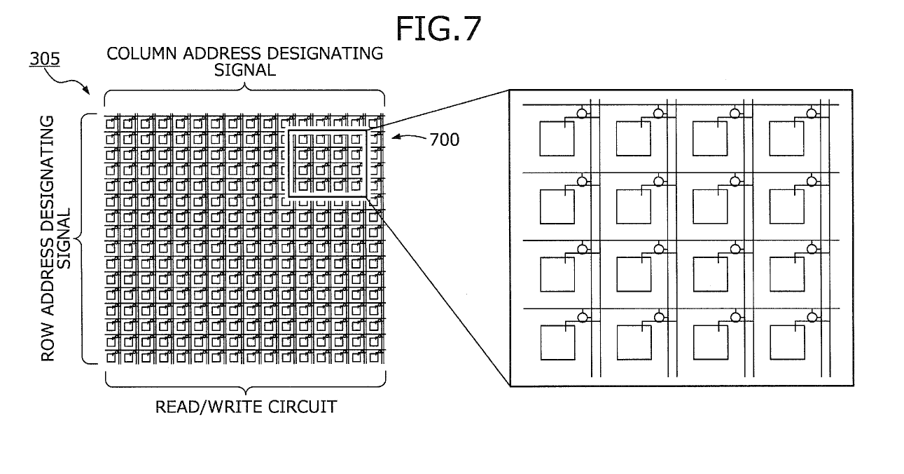

FIG. 7 is a diagram of an example of a memory cell array of the DRAM 305. In FIG. 7, a memory cell array 700 of the DRAM 305 is depicted. The memory cell array 700 includes plural memory cells arranged in a given row and a given column.

Here, read and write circuits are provided for the memory cells in the DRAM 305. Row address specifying signal lines and column address specifying signal lines are connected to the memory cells, where the read and write circuits detect the input of a signal to the row and address specifying signal line, enabling the memory cell subject to control to be identified.

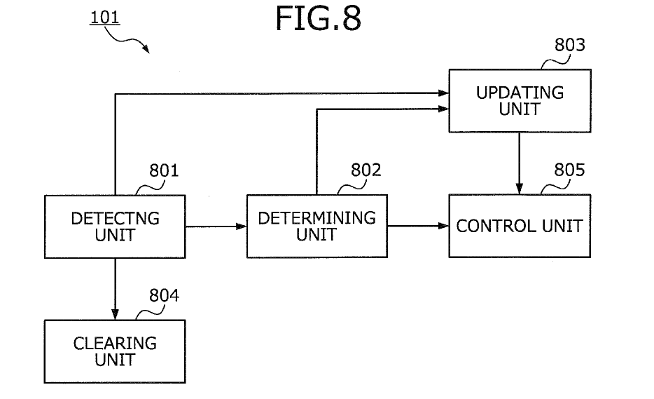

A functional configuration example of the control device 101 will be described. FIG. 8 is a block diagram of a functional configuration example of the control device 101. In FIG. 8, the control device 101 includes a detecting unit 801, a determining unit 802, an updating unit 803, a clearing unit 804, and a control unit 805. The functional units, for example, may be implemented by hardware. For example, the functional units may be configured by elements such as an AND circuit, an INVERTER circuit, an OR circuit, a NOR circuit, and flip flops (FF), which are latch circuits. Further, each of the functional units may be functionally defined by description in, for example, Verilog-Hardware Description Language (HDL) and by logically synthesizing the description, may be implemented by a Field Programmable Gate Array (FPGA). The functional units may be implemented by executing on the computing apparatus 306, a program that implements the functions of the functional units, for example. The program, for example, is stored in the memory unit 307.

The detecting unit 801 has a function of detecting an access request for a given memory area in the DRAM 305. For example, the detecting unit 801 detects a write request or a read request for the given memory area by receiving the write request or read request from the CPU 301.

In the description hereinafter, the given memory area that is to be accessed and corresponds to the access request may be indicated as “access area AR”. Further, a write request for the access area AR may be indicated as “write request W”. A read response corresponding to a read request for the access area AR may be indicated as “read response R”.

The detecting unit 801 has a function of detecting a clear command that clears information stored in the given memory area in the DRAM 305. For example, the detecting unit 801 detects the clear command for the given memory area by receiving from the CPU 301, a clear command for the given memory area.

In the description hereinafter, the given memory area subject to clearing and corresponding to the clear command may be indicated as “clear area CR”. Further, the clear command for the clear area CR may be indicated as “clear command C”.

The determining unit 802 has a function of determining whether all of the write_information written to the access area AR and corresponding to the detected access request is “0”. For example, the determining unit 802 determines whether all of the write_information included in the data portion of the packet indicated by the detected write request W is “0”.

In the example of the packet 500 depicted in FIG. 5, the determining unit 802 determines that all of the write_information 521 included in the data portion 520 is “0”. In the example of the packet 600 depicted in FIG. 6, the determining unit 802 determines that the write_information 621 included in a data portion 620 includes “1”.

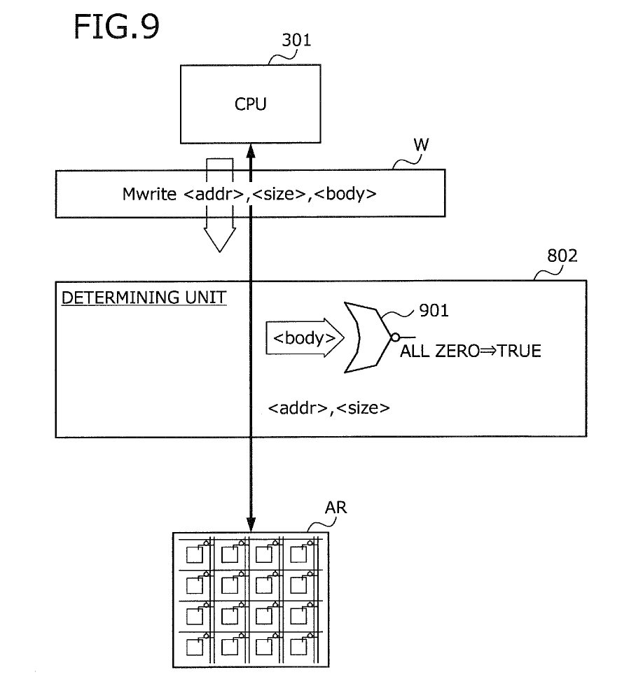

The determining unit 802 has a function of determining whether all read_information that is to be read from an access area AR according to a detected access request is “0”. For example, the determining unit 802 determines whether all read_information included in the data portion of the packet indicated by the read response R for a detected read request is “0”. An operation example of the determining unit 802 will be described hereinafter with reference to FIG. 9.

The updating unit 803 has a function of updating the clear flag of a memory area Ri. For example, if all of the write_information written to the access area AR is determined to be “0”, the updating unit 803 refers to the clear flag table 400 (see FIG. 4) and identifies from among the memory areas R1 to Rn, a memory area Ri included in the access area AR. The updating unit 803 updates the clear flag of the memory area Ri to “Clr”.

Further, the updating unit 803, for example, refers to the clear flag table 400 and identifies from among the memory areas R1 to Rn, a memory area Ri included in the access area AR, if all of the read_information read from the access area AR is “0”. The updating unit 803 updates the clear flag of the identified memory area Ri to “Clr”.

If plural memory areas are included in the access area AR, configuration may be such that the updating unit 803 updates the clear flag for each memory area included in the access area AR.

If a clear command C for a clear area CR is detected, the updating unit 803, for example, refers to the clear flag table 400 and identifies from among the memory areas R1 to Rn, a memory area Ri included in the clear area CR. The updating unit 803 updates the clear flag of the identified memory area Ri to “Clr”.

If the clear area CR includes plural memory areas, configuration may be such that the updating unit 803 changes the clear flag of each memory area included in the clear area CR to “Clr”.

The clearing unit 804 has a function of clearing the stored contents of the clear area Cr, if a clear command C for the clear area CR is detected. For example, the clearing unit 804 clears the stored contents of the clear area CR by opening the charge of the memory cells included in the clear area CR.

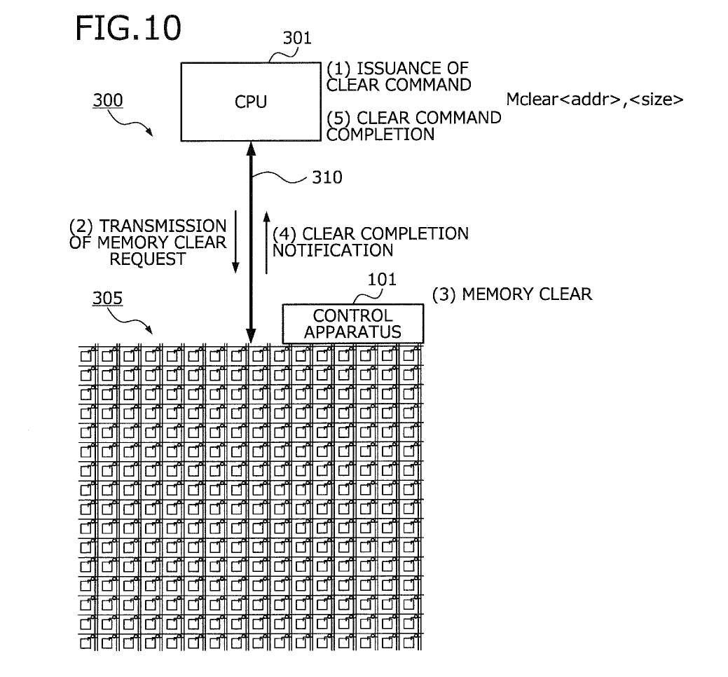

Configuration may be such that the clearing unit 804 clears the stored contents of the clear area CR by writing over meaningless information in the clear area CR. With reference to FIG. 10, an operation example of the system 300 will be described hereinafter for a clear process of clearing the stored contents of the clear area CR.

The control unit 805 has a function of controlling the refresh operation for the memory area Ri, based on obtained determination results. For example, if all of the write_information written to the access area AR is “0”, the control unit 805 suspends the refresh operation for the access area AR.

Further, the control unit 805, for example, suspends the refresh operation for the access area AR, if the read_information read from the access area AR are all “0”. For example, if a clear command C for the clear area CR is detected, the control unit 805 suspends the refresh operation of the clear area CR.

For example, the control unit 805 refers to the clear flag table 400 and controls the refresh operation, which is periodically performed for the memory cells of the DRAM 305. For example, the control unit 805 refers to the clear flag table 400 and if the clear flag of the memory area Ri selected from among the memory areas R1 to Rn indicates “Clr”, the control unit 805 suspends the refresh operation periodically performed for the memory cells in the memory area Ri. On the other hand, if the clear flag of the memory area Ri indicates “No-clr”, the control unit 805, for example, controls the read/write circuit of the DRAM 305 and performs the refresh operation for the memory cells in the memory area Ri.

Further, if the write_information written to the access area AR includes “1”, the updating unit 803 refers to the clear flag table 400 and identifies from among the memory areas R1 to Rn, a memory area Ri that includes at least one area of the access area AR. The updating unit 803 changes the clear flag of the identified memory area Ri to “No-clr”.

Thus, if “1” is stored to any of the memory cells of the access area AR, the clear flag of the memory area Ri that includes the memory cell, for example, the memory area Ri for which the refresh operation has been suspended can be changed from “Clr” to “No-clr”. If plural memory areas are present that include at least an area of the access area AR, the updating unit 803 changes the clear flag of each memory area that includes at least an area of the access area AR to “No-clr”.

Further, if the write_information written to the access area AR for which the refresh operation has been suspended includes “1”, the control unit 805 resumes the refresh operation for the access area AR. For example, the control unit 805 refers to the clear flag table 400 and if the clear flag of the memory area Ri selected from among the memory areas R1 to Rn indicate “No-clr”, the control unit 805 performs the refresh operation for the memory cell in the memory area Ri.

Thus, if “1” is written to any of the memory cells of the memory area Ri for which the refresh operation has been suspended, the periodic refresh operation for the memory area Ri can be resumed.

An operation example of the determining unit 802 will be described taking a case where a write request W for an access area AR is detected.

FIG. 9 is a diagram of an operation example of the determining unit 802. In FIG. 9, when a write request W from the CPU 301 and for an access area AR is input, the determining unit 802 checks whether all of the write_information included in the data portion (in FIG. 9, <body>) of the write request W is “0”.

For example, if write_information included in the data portion of the write request W is input into the cell 901 and all of the write_information is “0”, a “true” signal is output from the cell 901. A “true” signal indicates that all of the write_information is “0”.

Although not depicted, similar to the case of a read response R, if the read_information included in the data portion of the read response R is input into the cell 901 and all of the read_information is “0”, a “true” signal is output from the cell 901. The determining unit 802, for example, can be implemented by an existing Error Check and Correct (ECC) or parity check.

An operation example of the system 300 will be described for a clear process of clearing the stored contents of a clear area CR. FIG. 10 is a diagram of an operation example for the clear process of the system 300.

(1) The CPU 301 issues to the control device 101, a clear command C for a clear area CR. The clear command C includes an address “<addr>” specifying the clear area CR and the size “<size>” of the clear area CR. When the clear command C is executed by the CPU 301, a memory clear bus transaction occurs.

(2) The CPU 301 transmits to the control device 101, via the bus 301, a memory clear request that includes the clear command C.

(3) The control device 101 clears the stored contents for the clear area CR designated by the clear command C. For example, plural address signal lines for a row and column are concurrently specified by the clear command C and the clear area CR formed by the plural rows and plural columns is specified. The clearing unit 804 clears the stored contents of the clear area CR by opening the charge of the memory cells included in the clear area CR.

(4) When the clear process of clearing the stored contents of the clear area CR ends, the control device 101 generates clear completion notification and via the bus 310, transmits the clear completion notification.

(5) The CPU 301 terminates the clear command C upon receiving the clear completion notification. Thus, when the clear process ends on the control device 101 side, the clear completion notification reaches the CPU 301 as a bus transaction, the CPU 301 terminates the clear command C, and the block of the clear command C is released.

According to the clear process described above, compared to executing a successive writing process for “0” by the CPU 301 or direct memory access (DMA), high speed clearing of a clear area CR can be realized. A detailed description of the clear process can be referred to in Japanese Laid-Open Patent Publication No. 2009-289117, for example.

A procedure of an updating process of updating in the clear flag table 400, the clear flag of the memory area Ri by the control device 101. Here, the procedure of the updating process in a case where an access request for an access area AR is detected will be described.

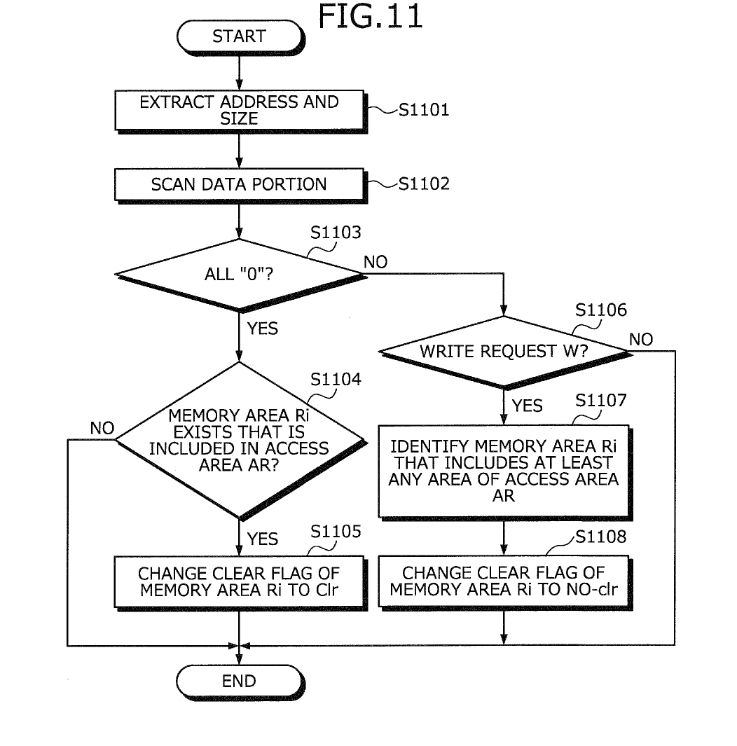

FIG. 11 is a flowchart (part 1) of an example of the procedure of the updating process by the control device 101. In the flowchart depicted in FIG. 11, when an access request for an access area AR is detected, the control device 101 extracts from the access request, the address and the size of the access area AR (step S1101).

The control device 101 scans the data portion of the access request, which is a write request W or a read response R for a read request (step S1102). The control device 101 determines whether all of the write_information or read_information included in the data portion is “0” (step S1103).

If all is “0” (step S1103: YES), the control device 101 refers to the clear flag table 400 and determines whether among the memory areas R1 to Rn, a memory area Ri included in the access area AR is present (step S1104). The access area AR is identified by the address and size extracted at step S1101.

If a memory area Ri included in the access area AR is present (step S1104: YES), the control device 101 changes in the clear flag table 400, the clear flag of the memory area Ri included in the access area AR to “Clr” (step S1105), ending a series of operations according to the present flowchart. On the other hand, if no memory area Ri included in the access area AR is present (step S1104: NO), the control device 101 ends a series of operations according to the present flowchart.

At step S1103, if “1” is included in the write_information or read_information (step S1103: NO), the control device 101 determines whether the access request is a write request W (step S1106). If the access request is a read request (step S1106: NO), the control device 101 ends a series of operations according to the present flowchart.

On the other hand, if the access request is a write request W (step S1106: YES), the control device 101 refers to the clear flag table 400 and identifies from among the memory areas R1 to Rn, a memory area Ri that includes at least an area of the access area AR (step S1107).

The control device 101 changes in the clear flag table 400, the clear flag of the identified memory area Ri to “No-clr” (step S1108), ending a series of operations according to the present flowchart.

Thus, if all of the write_information written to the access area AR is “0” or if all of the read_information read from the access area AR is “0”, the clear flag of the memory area Ri included in the access area AR can be changed to “Clr”. Further, if the write_information written to the access area AR includes “1”, the clear flag of the memory area Ri that includes at least an area of the access area AR can be changed to “No-clr”.

A case will be given where a write request W for an access area AR is detected and the refresh operation is controlled and an updating process procedure for the clear flag table 400 when a write request W for the access area AR has been detected will be described.

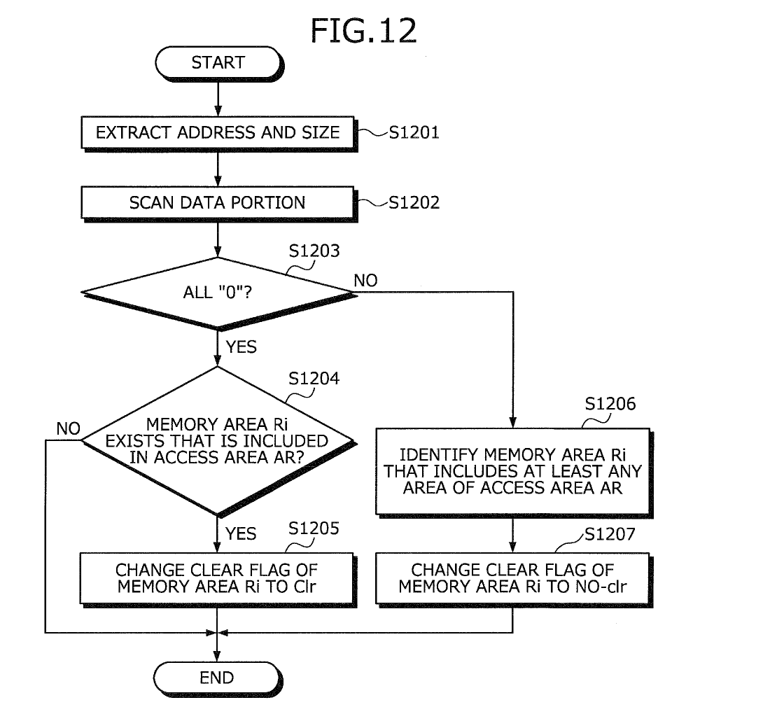

FIG. 12 is a flowchart (part 2) of an example of the procedure of the updating process by the control device 101. In the flowchart depicted in FIG. 12, when a write request W for an access area AR is detected, the control device 101 extracts from the write request W for the access area AR, the address and the size of the access area AR (step S1201).

The control device 101 scans the data portion of the write request W (step S1202). The control device 101 determines whether all of the write_information included in the data portion is “0” (step S1203).

If all of the write_information is “0” (step S1203: YES), the control device 101 refers to the clear flag table 400 and determines whether among the memory areas R1 to Rn, a memory area Ri included in the access area AR is present (step S1204).

If a memory area Ri included in the access area AR is present (step S1204: YES), the control device 101 changes in the clear flag table 400, the clear flag of the memory area Ri included in the access area AR to “Clr” (step S1205), ending a series of operations according to the present flowchart. On the other hand, if no memory area Ri included in the access area AR is present (step S1204: NO), the control device 101 ends a series of operations according to the present flowchart.

At step S1203, if “1” is included in the write_information (step S1203: NO), the control device 101 refers to the clear flag table 400 and identifies from among the memory areas R1 to Rn, a memory area Ri that includes at least an area of the access area AR (step S1206).

The control device 101 changes the clear flag of the identified memory area Ri to “No-clr” in the clear flag table 400 (step S1207), ending a series of operations according to the present flowchart.

Thus, if all of the write_information written to the access area AR is “0”, the clear flag of the memory area Ri included in the access area AR can be changed to “Clr”. Further, if the write_information written to the access area AR includes “1”, the clear flag of the memory area Ri that includes at least an area of the access area AR can be changed to “No-clr”.

A procedure of the updating process in a case where a clear command C for the clear area CR is detected will be described.

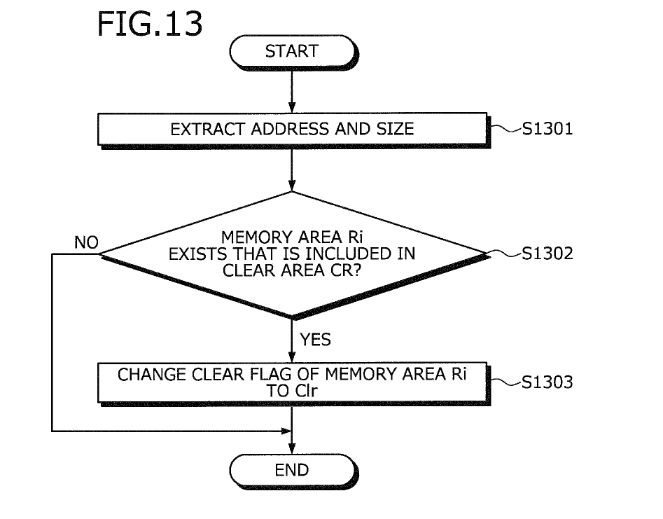

FIG. 13 is a flowchart (part 3) of the procedure of the updating process by the control device 101. In the flowchart depicted in FIG. 13, if a clear command C for a clear area CR is detected, the control device 101 extracts the address and the size of the clear area Cr from the clear command C for the clear area CR (step S1301).

The control device 101 refers to the clear flag table 400 and determines whether among the memory areas R1 to Rn, a memory area Ri that is included in the clear area CR is present (step S1302). The clear area CR is identified from the address and the size extracted at step S1301.

If a memory area Ri that is included in the clear area CR is present (step S1302: YES), the control device 101 changes the clear flag of the memory area Ri included in the clear area CR to “Clr” in the clear flag table 400 (step S1303), ending a series of operations according to the present flowchart. On the other hand, if no memory area Ri included in the clear area CR is present (step S1302: NO), the control device 101 ends a series of operations according to the present flowchart.

Thus, when a clear command for a clear area CR is detected, the clear flag of the memory area Ri included in the clear area CR can be changed to “Clr”. The updating process of the control device 101 depicted in FIG. 13, for example, is executed in parallel with the updating process of the control device 101 depicted in FIG. 11 or the updating process of the control device depicted in FIG. 12.

A procedure of a control process by the control device 101, for controlling the refresh operation for the memory area Ri will be described. This control process, for example, may be periodically executed at preliminarily set intervals. The interval, for example, may be set such that the memory cells are refreshed at cycles of several μs or several tens of μs.

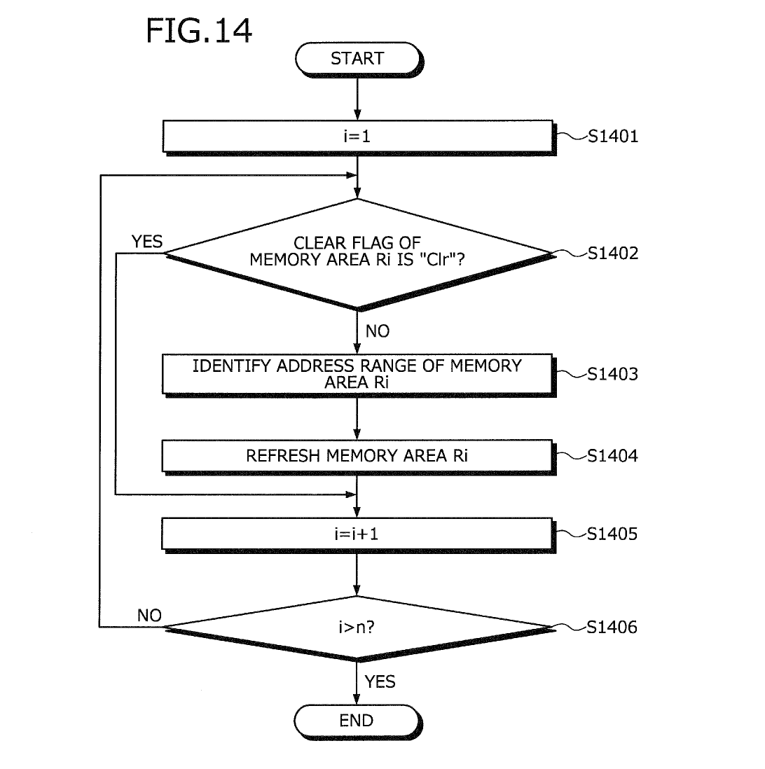

FIG. 14 is a flowchart of an example of a procedure of the control process by the control device 101. In the flowchart depicted in FIG. 14, the control device 101 sets “i” of the memory area Ri in the DRAM 305 as “i=1” (step S1401)

The control device 101 refers to the clear flag table 400 and determines whether the clear flag of the memory area Ri indicates “Clr” (step S1402). If a clear flag indicating “Clr” is present (step S1402: YES), the control device 101 transitions to step S1405.

On the other hand, if the clear flag indicates “No-clr” (step S1402: NO), the control device 101 refers to the clear flag table 400 and identifies an address range of the memory area Ri (step S1403). The control device 101 controls the read/write circuit of the DRAM 305 and refreshes the memory area Ri of the identified address range (step S1404).

The control device 101 increments “i” of the memory area Ri (step S1405), and determines whether “i” is greater than “n” (step S1406). If “i” is “n” or less (step S1406: NO), the control device 101 returns to step S1402.

On the other hand, if “i” is greater than “n” (step S1406: YES), the control device 101 ends a series of operations according to the present flowchart. Thus, among the memory areas R1 to Rn, the refresh operation of a memory area Ri for which the clear flag indicates “Clr” can be suspended.

According to the control device 101 of the third embodiment, if a write request W for an access area AR is detected, whether all of the write_information written to the access area AR is “0” can be determined. According to the control device 101, if all of the write_information written to the access area AR is “0”, the refresh operation for the memory area Ri included in the access area AR can be suspended.

According to the control device 101 of the third embodiment, if a read request for an access area AR is detected, whether all of the read_information read from the access area AR is “0” can be determined. Further, according to the control device 101, if all of the read_information read from the access area AR is “0”, the refresh operation for the memory area Ri included in the access area AR can be suspended.

According to the control device 101 of the third embodiment, if a clear command C for a clear area CR is detected, the refresh operation for a memory unit Ri included in the clear area CR can be suspended.

Thus, according to the control device 101, the refresh operation is suspended for a memory area Ri for which the stored contents are assured to be “0” and the power consumption for the refresh operation of the DRAM 305 can be suppressed. By managing the memory area Ri in units of 1[KB], 4[KB], and 16[KB] pages, the refresh operation for the memory area Ri can be efficiently controlled.

According to the control device 101 of the third embodiment, if the write_information written to an access area AR includes “1”, a memory area Ri that includes at least an area of the access area AR can be identified from among the memory areas R1 to Rn. According to the control device 101, the clear flag of the identified memory area Ri can be changed to “No-clr”.

Thus, the refresh operation can be resumed for a memory area Ri for which the stored contents are not assured to be “0” and the stored contents of the memory area Ri can be retained.

The control method described in the present embodiment may be implemented by executing a prepared program on a computer such as a personal computer and a workstation. The control program is stored on a non-transitory, computer-readable recording medium such as a hard disk, a flexible disk, a CD-ROM, an MO, and a DVD, read out from the computer-readable medium, and executed by the computer. The control program may be distributed through a network such as the Internet.

The control device 101 described in the present embodiments can be realized by an application specific integrated circuit (ASIC) such as a standard cell or a structured ASIC, or a programmable logic device (PLD) such as a field-programmable gate array (FPGA). Specifically, for example, functional units of the control device 101 are defined in hardware description language (HDL), which is logically synthesized and applied to the ASIC, the PLD, etc., thereby enabling manufacture of the control device 101.

According to one aspect of the embodiments, an effect is achieved in that the power consumed for the refresh operation of the memory can be suppressed.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A control device comprising
circuits configured to:
detect an access request for a memory area in memory that stores information by charging and discharging charge;
determining whether any one among write_information written to the memory area that corresponds to the detected access request and read_information read from the memory area coincides with information stored in the memory area when charge is discharged; and
performing control to suspend a refresh operation for the memory area when any one among the write_information and the read_information is determined to coincide with the information stored in the memory when the charge is discharged.

2. The control device according to claim 1, wherein
the circuits detect a clear command for clearing the information stored in the memory area, and
the circuits suspend the refresh operation for the memory area, when the clear command is detected.

3. The control device according to claim 1, wherein
the circuits detect a write request for the memory area for which the refresh operation has been suspended,
the circuits determine whether the write_information writing to the memory area that corresponds to the write request coincides with the information stored in the memory area when the charge is discharged, and
the circuits resume the refresh operation for the memory area, when the write_information coincides with the information stored in the memory area when the charge is released.

4. A control device comprising
circuits configured to:
detect a clear command for clearing information stored in a memory area in memory that stores the information by charging and discharging charge; and
perform control to suspend a refresh operation for the memory area, when the clear command is detected.

5. A control method comprising:
detecting, by a computer, an access request for a memory area in memory that stores information by charging and discharging charge;
determining, by the computer, whether any one among write_information written to the memory area that corresponds to the detected access request and read_information read from the memory area coincides with information stored in the memory area when charge is discharged; and
suspending, by the computer, a refresh operation for the memory area when any one among the write_information and the read_information is determined to coincide with the information stored in the memory area when the charge is discharged.

6. A control method comprising:
detecting, by a computer, a clear command for clearing information stored in a memory area of memory that stores the information by charging and discharging charge; and
suspending, by the computer, a refresh operation for the memory area, when the clear command is detected.
